(19) United States
(12) Patent Application Publication
(10) Pub. No.: US 2022/0301650 A1
(43) Pub. Date: Sep. 22, 2022

(54) CONTROLLER CONTROLLING SEMICONDUCTOR MEMORY DEVICE AND METHOD OF OPERATING THE CONTROLLER

(71) Applicant: SK hynix Inc., Gyeonggi-do (KR)

(72) Inventors: Ki Woong LEE, Gyeonggi-do (KR); Chan Young OH, Gyeonggi-do (KR)

(21) Appl. No.: 17/461,749

(22) Filed: Aug. 30, 2021

(30) Foreign Application Priority Data
Mar. 16, 2021 (KR) 10-2021-0034198

(51) Int. Cl. G11C 29/12; G11C 29/42; G11C 29/44; G11C 16/26; G11C 16/34

(52) U.S. Cl. CPC G11C 29/12005; G11C 29/42; G11C 29/4401; G11C 16/26; G11C 16/3404

(57) ABSTRACT

The present technology provides a method of operating a controller that controls a semiconductor memory device including a plurality of memory cells. The method of operating the controller includes controlling the semiconductor memory device to perform a read operation on selected memory cells among the plurality of memory cells by using a read voltage set including at least one read voltage, receiving read data from the semiconductor memory device, and changing at least one read voltage included in the read voltage set by counting, based on the read data, a number of memory cells each having a threshold voltage lower than the at least one read voltage included in the read voltage set.

### CROSS-REFERENCE TO RELATED APPLICATION

The present application claims priority under 35 U.S.C. § 119(a) to Korean patent application number 10-2021-0034198 filed on Mar. 16, 2021, the entire disclosure of which is incorporated by reference herein.

### BACKGROUND

### Field of Invention

The present disclosure relates to an electronic device, and more particularly, to a controller controlling a semiconductor memory device and a method of operating the controller.

### Description of Related Art

A semiconductor memory device may be formed in a two-dimensional structure in which strings are horizontally arranged on a semiconductor substrate, or in a three-dimensional structure in which the strings are vertically stacked on the semiconductor substrate. A three-dimensional memory device is a memory device designed in order to resolve a limit of an integration degree of a two-dimensional semiconductor memory device, and may include a plurality of memory cells that are vertically stacked on a semiconductor substrate. A controller may control an operation of the semiconductor memory device,

### SUMMARY

An embodiment of the present disclosure provides a controller with improved read performance and a method of operating the same,

According to an embodiment of the present disclosure, a method of operating a controller that controls a semiconductor memory device including a plurality of memory cells is provided. The method of operating the controller includes controlling the semiconductor memory device to perform a read operation on selected memory cells among the plurality of memory cells by using a read voltage set including at least one read voltage, receiving read data from the semiconductor memory device, and changing at least one read voltage included in the read voltage set by counting, based on the read data, a number of memory cells each having a threshold voltage lower than the at least one read voltage included in the read voltage set.

In an embodiment of the present disclosure, the method of operating the controller may further include performing an error correction operation on the received read data. The changing the at least one read voltage included in the read voltage set may be performed in response to a determination that the error correction operation has failed on the received read data.

In an embodiment of the present disclosure, the method of operating the controller may further include controlling, after the changing the at least one read voltage, the semiconductor memory device to perform the read operation on the selected memory cells among the plurality of memory cells by using the read voltage set including the changed read voltage,

in an embodiment of the present disclosure, the read voltage set may include first to N-th read voltages, where N is a natural number greater than or equal to 1. The changing the at least one read voltage included in the read voltage set may include counting the number of memory cells each having the threshold voltage lower than an i-th read voltage among the first to N-th read voltages, where ‘i’ is a natural number greater than or equal to 1 and less than or equal to N, comparing the number of memory cells each having the threshold voltage lower than the i-th read voltage with an i-th lower threshold value, and increasing the i-th read voltage, in response to a determination that the number of memory cells each having the threshold voltage lower than the i-th read voltage is less than the i-th lower threshold value.

In an embodiment of the present disclosure, the increasing the i-th read voltage may include increasing the i-th read voltage by a predetermined voltage value,

In an embodiment of the present disclosure, the increasing the i-th read voltage may include increasing the i-th read voltage by a voltage value determined according to a difference between the i-th lower threshold value and the number of memory cells each having the threshold voltage lower than the i-th read voltage.

In an embodiment of the present disclosure, the read voltage set may include first to N-th read voltages, where N is a natural number greater than or equal to 1. The changing the at least one read voltage included in the read voltage set may include counting the number of memory cells each having the threshold voltage lower than an i-th read voltage among the first to N-th read voltages, where a natural number greater than or equal to 1 and less than or equal to N, comparing the number of memory cells each having the threshold voltage lower than the i-th read voltage with an i-th upper threshold value, and decreasing the i-th read voltage, in response to a determination that the number of memory cells each having the threshold voltage lower than the i-th read voltage is greater than the i-th upper threshold.

In an embodiment of the present disclosure, the decreasing the i-th read voltage may include decreasing the i-th read voltage by a predetermined voltage value.

in an embodiment of the present disclosure, the decreasing the i-th read voltage may include decreasing the i-th read voltage by a voltage value determined according to a difference between the number of memory cells each having the threshold voltage lower than the i-th read voltage and the i-th upper threshold value.

According to another embodiment of the present disclosure, a controller controlling a semiconductor memory device including a plurality of memory cells is provided. The controller includes a read voltage controller configured to control a magnitude of at least one read voltage included in a read voltage set used during a read operation on selected memory cells among the plurality of memory cells, and a memory cell counter configured to count, based on read data received from the semiconductor memory device, a number of memory cells each having a threshold voltage lower than the at least one read voltage among the selected memory cells. The read voltage controller controls the magnitude by changing the at least one read voltage based on a result of the counting,

In an embodiment of the present disclosure, the controller may further include an error correction block configured to perform an error correction operation on the received read data. The memory cell counter may count the number of memory cells each having the threshold voltage lower than the at least one read voltage among the selected memory cells, in response to a determination of the error correction block that error correction operation on the received read data has been failed.

In an embodiment of the present disclosure, the read voltage set may include first to Nth read voltages, where N is a natural number greater than or equal to 1, The memory cell counter may count the number of memory cells each having a threshold voltage lower than an i-th read voltage among first to Nth read voltages, where T is a natural number greater than or equal to 1 and less than or equal to N.

In an embodiment of the present disclosure, the read voltage controller may compare the number of memory cells each having the threshold voltage lower than the i-th read voltage with an i-th lower threshold value. The read voltage controller may change the at least one read voltage by increasing the i-th read voltage in response to a determination that the number of memory cells each having the threshold voltage lower than the i-th read voltage is less than the i-th lower threshold.

In an embodiment of the present disclosure, the read voltage controller may increase the i-th read voltage by a predetermined voltage value.

In an embodiment of the present disclosure, the read voltage controller may increase the i-th read voltage by a voltage value determined according to a difference between the i-th lower threshold value and the number of memory cells each having the threshold voltage lower than the i-th read voltage.

In an embodiment of the present disclosure, the read voltage controller may compare the number of memory cells each having the threshold voltage lower than the i-th read voltage with an i-th upper threshold value. The read voltage controller may change the at least one read voltage by decreasing the i-th read voltage in response to a determination that the number of memory cells each having the threshold voltage lower than the i-th read voltage is greater than the i-th upper threshold value.

in an embodiment of the present disclosure, the read voltage controller may decrease the i-th read voltage by a predetermined voltage value,

in an embodiment of the present disclosure, the read voltage controller may decrease the i-th read voltage by a voltage value determined according to a difference between the number of memory cells each having the threshold voltage lower than the i-th read voltage and the i-th upper threshold.

According to still another embodiment of the present disclosure, an operating method of a controller is provided. The operating method includes controlling a memory device to perform a first read operation on a cell group with a first read voltage, and controlling the memory device to performing second read operation on the cell group with a second read voltage when the first read operation fails and indicates a number of on-cells, which is out of a threshold range, as a result thereof.

In an embodiment of the present disclosure, the operating method may further include adjusting the first read voltage by a predetermined amount to define the second read voltage.

In an embodiment of the present disclosure, the adjusting may include increasing the first read voltage when the number is less than the threshold range, and decreasing the first read voltage when the number is greater than the threshold range.

In an embodiment of the present disclosure, the operating method may further include adjusting the first read voltage by an amount, which corresponds to a deviation of the number with respect to the threshold range, to define the second read voltage.

In an embodiment of the present disclosure, the adjusting may include increasing, when the number is less than the threshold range, the first read voltage by the amount corresponding to the deviation from a lower limit of the threshold range, and decreasing, when the number is greater than the threshold range, the first read voltage by the amount corresponding to the deviation from an upper limit of the threshold range.

The present technology may provide a controller with improved read performance and a method of operating the same.

### BRIEF DESCRIPTION OF THE DRAWINGS

FIG. 1 is a block diagram illustrating a memory system including a controller according to an embodiment of the present disclosure.

FIG. 2 is a block diagram illustrating a semiconductor memory device according to an embodiment of the present disclosure.

FIG. 3 is a diagram illustrating the memory cell array of FIG. 2 according to an embodiment of the present disclosure.

FIG. 4 is a circuit diagram illustrating a memory block BLKa of memory blocks BLK1 to BLKz of FIG. 3 according to an embodiment of the present disclosure.

FIG. 5 is a circuit diagram illustrating another memory block BLKb of the memory blocks BLK1 to BLKz of FIG. 3 according to an embodiment of the present disclosure.

FIG. 6 is a circuit diagram illustrating a memory block BLKc of the memory blocks BLK1 to BLKz included in a memory cell array 110 of FIG. 2 according to an embodiment of the present disclosure.

FIG. 7 is a graph illustrating a threshold voltage distribution of a multi-level cell (MLC) according to an embodiment of the present disclosure.

FIG. 8 is a graph illustrating a read voltage set which is changed when there is a change of a threshold voltage distribution of memory cells according to an embodiment of the present disclosure.

FIG. 9 is a flowchart illustrating a method of operating a controller according to an embodiment of the present disclosure.

FIG. 10 is a flowchart illustrating an embodiment of operation S190 of FIG. 9 according to an embodiment of the present disclosure.

FIGS. 11A, 11B, 11C, and 11D are graphs illustrating a method of changing a read voltage of FIG. 10 according to an embodiment of the present disclosure.

FIG. 12 is a flowchart illustrating another embodiment of operation S190 of FIG. 9 according to an embodiment of the present disclosure.

FIGS. 13A and 13B are graphs illustrating a method of changing a read voltage of FIG. 12 according to an embodiment of the present disclosure.

FIG. 14 is a block diagram illustrating a memory system including the controller of FIG. 1 according to an embodiment of the present disclosure.

FIG. 15 is a block diagram illustrating an application example of the memory system of FIG. 14 according to an embodiment of the present disclosure.

FIG. 16 is a block diagram illustrating a computing system including the memory system described with reference to FIG. 15 according to an embodiment of the present disclosure.

### DETAILED DESCRIPTION

Specific structural or functional descriptions of embodiments according to the concept which are disclosed in the present specification are illustrated only to describe the embodiments according to the concept of the present disclosure, The embodiments according to the concept of the present disclosure may be carried out in various forms and should not be construed as being limited to the embodiments described in the present specification.

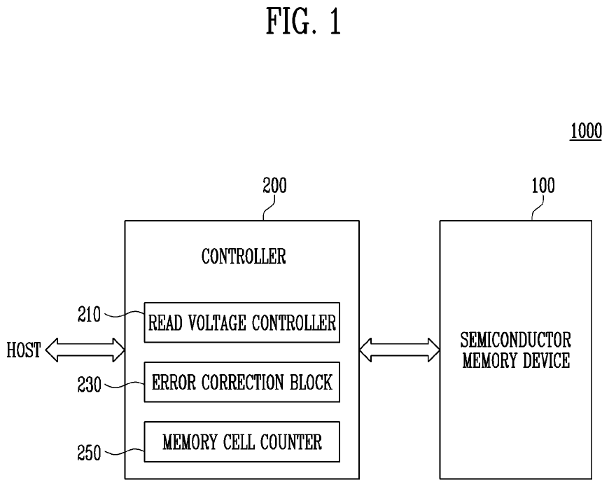

FIG. 1 is a block diagram illustrating a memory system 1000 including a controller according to an embodiment of the present disclosure.

Referring to FIG. 1, the memory system 1000 includes a semiconductor memory device 100 and a controller 200. In addition, the memory system 1000 communicates with a host. Each of the semiconductor memory device 100 and the controller 200 may be provided as one chip, one package, and one device. Alternatively, the memory system 1000 may be provided as one storage device.

The controller 200 controls an overall operation of the semiconductor memory device 100. In addition, the controller 200 controls an operation of the semiconductor memory device 100 based on a command request received from the host.

The semiconductor memory device 100 operates under control of the controller 200. The semiconductor memory device 100 includes a memory cell array having a plurality of memory blocks. In an embodiment, the semiconductor memory device 100 may be a flash memory device.

The controller 200 may receive a write request or a read request of data from the host, and control the semiconductor memory device 100 based on the received requests. More specifically, the controller 200 may generate commands for controlling the operation of the semiconductor memory device 100 and transmit the commands to the semiconductor memory device 100.

The semiconductor memory device 100 is configured to receive a command and an address from the controller 200 and to access an area selected by the address of the memory cell array. That is, the semiconductor memory device 100 performs an internal operation corresponding to a command on the area selected by the address.

For example, the semiconductor memory device 100 may perform a program operation, a read operation, and an erase operation. During the program operation, the semiconductor memory device 100 may program data in the area selected by the address. During the read operation, the semiconductor memory device 100 may read data from the area selected by the address. During the erase operation, the semiconductor memory device 100 may erase data stored in the area selected by the address.

The controller 200 includes a read voltage controller 210, an error correction block 230, and a memory cell counter 250. The read voltage controller 210, the error correction block 230, and the memory cell counter 250 include all circuits, systems, software, firmware and devices necessary for their respective operations and functions.

The read voltage controller 210 may manage and adjust read voltages for reading data stored in the semiconductor memory device 100. For example, when data read from the semiconductor memory device 100 is not corrected by the error correction block 230, the read voltage controller 210 may adjust at least one read voltage used for the read operation of the semiconductor memory device 100. According to the present disclosure, the read voltage controller 210 may adjust the read voltage used for the read operation of the semiconductor memory device 100, based on the number of memory cells, that is, on-cells each having a threshold voltage lower than a specific read voltage. The number may be counted by the memory cell counter 250.

The error correction block 230 is configured to detect and correct an error of the data received from the semiconductor memory device 100 using an error correction code (ECC). The read voltage controller 210 may control the semiconductor memory device 100 to adjust the read voltage and perform a re-read according to an error detection result of the error correction block 230. For example, the error correction block 230 may generate an error correction code for data to be stored in the semiconductor memory device 100. The generated error correction code may be stored in the semiconductor memory device 100 together with the data. Thereafter, the error correction block 230 may detect and correct the error of the data read from the semiconductor memory device 100, based on the stored error correction code. For example, the error correction block 230 has a predetermined error correction capability. Data including an error bit (or fail bit) exceeding the error correction capability of the error correction block 230 is referred to as ‘uncorrectable ECC (UECC) data’. When the data read from the semiconductor memory device 100 is the UECC data, the read voltage controller 210 may control the semiconductor memory device 100 to perform the read operation again by adjusting the read voltages.

The memory cell counter 250 may count the number of memory cells each having a threshold voltage lower than a specific read voltage, based on the read data received from the semiconductor memory device 100. A result of the counting operation as described above is transmitted to the read voltage controller 210. The read voltage controller 210 may adjust the read voltage used for the read operation of the semiconductor memory device 100, based on the count result received from the memory cell counter 250.

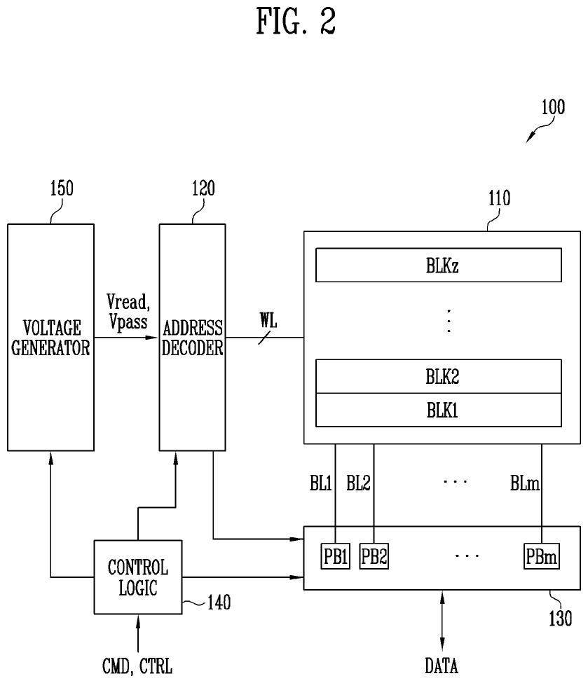

FIG. 2 is a block diagram illustrating a semiconductor memory device 100 according to an embodiment of the present disclosure.

Referring to FIG. 2, the semiconductor memory device 100 includes a memory cell array 110, an address decoder 120, a read and write circuit 130, a control logic 140, and a voltage generator 150.

The memory cell array 110 includes a plurality of memory blocks BLK1 to BLKz. The plurality of memory blocks BLK1 to BLKz are connected to the address decoder 120 through word lines WL. The plurality of memory blocks BLK1 to BLKz are connected to the read and write circuit 130 through bit lines BL1 to BLm. Each of the plurality of memory blocks BLK1 to BLKz includes a plurality of memory cells. In an embodiment, the plurality of memory cells are non-volatile memory cells, and may be configured of non-volatile memory cells having a vertical channel structure. The memory cell array 110 may be configured as a memory cell array of a two-dimensional structure. According to an embodiment, the memory cell array 110 may be configured as a memory cell array of a three-dimensional structure. Each of the plurality of memory cells included in the memory cell array may store at least one bit of data. In an embodiment, each of the plurality of memory cells included in the memory cell array 110 may be a single-level cell (SLC) storing one bit of data. In another embodiment, each of the plurality of memory cells included in the memory cell array 110 may be a multi-level cell (MLC) storing two bits of data. In still another embodiment, each of the plurality of memory cells included in the memory cell array 110 may be a triple-level cell storing three bits of data. In still another embodiment, each of the plurality of memory cells included in the memory cell array 110 may be a quad-level cell storing four bits of data. According to an embodiment, the memory cell array 110 may include a plurality of memory cells each storing five or more bits of data.

The address decoder 120, the read and write circuit 130, the control logic 140, and the voltage generator 150 operate as a peripheral circuit that drives the memory cell array 110. The address decoder 120 is connected to the memory cell array 110 through the word lines WL. The address decoder 120 is configured to operate in response to control of the control logic 140. The address decoder 120 receives an address through an input/output buffer (not shown) inside the semiconductor memory device 100. When power is supplied to the semiconductor memory device 100, information stored in a cam block is read out by the peripheral circuit, and the peripheral circuit may control the memory cell array to perform data input/output operations of the memory cells in a condition set according to the read information.

The address decoder 120 is configured to decode a block address among received addresses. The address decoder 120 selects at least one memory block according to the decoded block address. In addition, the address decoder 120 applies a read voltage Vread generated in the voltage generator 150 to a selected word line of the selected memory block at a time of a read voltage application operation during a read operation, and applies a pass voltage Vpass to the remaining unselected word lines. In addition, during a program verify operation, the address decoder 120 applies a verify voltage generated in the voltage generator 150 to the selected word line of the selected memory block, and applies the pass voltage Vpass to the remaining unselected word lines.

The address decoder 120 is configured to decode a column address of the received addresses. The address decoder 120 transmits the decoded column address to the read and write circuit 130.

A read operation and a program operation of the semiconductor memory device 100 are performed in a page unit. Addresses received at a time of a request of the read operation and the program operation include a block address, a row address, and a column address. The address decoder 120 selects one memory block and one word line according to the block address and the row address. The column address is decoded by the address decoder 120 and is provided to the read and write circuit 130. In the present specification, memory cells connected to one word line may be referred to as one “physical page”.

The address decoder 120 may include a block decoder, a row decoder, a column decoder, an address buffer, and the like.

The read and write circuit 130 includes a plurality of page buffers PB1 to PBm. The read and write circuit 1313 may operate as a “read circuit” during a read operation of the memory cell array 110 and may operate as a “write circuit” during a write operation of the memory cell array 110. The plurality of page buffers PB1 to PBm are connected to the memory cell array 110 through the bit lines BL1 to BLm. During the read operation and the program verify operation, in order to sense a threshold voltage of the memory cells, the plurality of page buffers PB1 to PBm sense a change of an amount of a current flowing according to a program state of a corresponding memory cell through a sensing node while continuously supplying a sensing current to the bit lines connected to the memory cells, and latches the sensed change as sensing data. The read and write circuit 130 operates in response to page buffer control signals output from the control logic 140.

During the read operation, the read and write circuit 130 senses data of the memory cell, temporarily stores read data, and outputs data DATA to the input/output buffer (not shown) of the semiconductor memory device 100. In an embodiment, the read and write circuit 130 may include a column selection circuit, and the like, in addition to the page buffers (or page registers).

The control logic 140 is connected to the address decoder 120, the read and write circuit 130, and the voltage generator 150. The control logic 140 receives a command CMD and a control signal CTRL through the input/output buffer (not shown) of the semiconductor memory device 100. The control logic 140 is configured to control overall operations of the semiconductor memory device 100 in response to the control signal CTRL. In addition, the control logic 140 outputs a control signal for adjusting a sensing node pre-charge potential level of the plurality of page buffers PB1 to PBm. The control logic 140 may control the read and write circuit 130 to perform the read operation of the memory cell array 110.

The voltage generator 150 generates the read voltage Vread and the pass voltage Vpass during the read operation in response to the control signal output from the control logic 140. In order to generate a plurality of voltages having various voltage levels, the voltage generator 150 may include a plurality of pumping capacitors that receive an internal power voltage, and generate the plurality of voltages by selectively activating the plurality of pumping capacitors in response to the control of the control logic 140.

The address decoder 120, the read and write circuit 130, and the voltage generator 150 may function as a “peripheral circuit” that performs a read operation, a write operation, and an erase operation on the memory cell array 110. The peripheral circuit performs the read operation, the write operation, and the erase operation on the memory cell array 110 based on the control of the control logic 140.

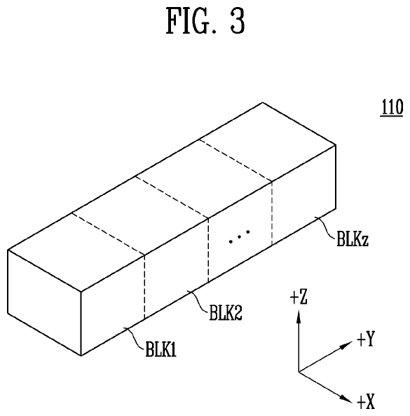

FIG. 3 is a diagram illustrating the memory cell array 110 of FIG. 2 according to an embodiment of the present disclosure.

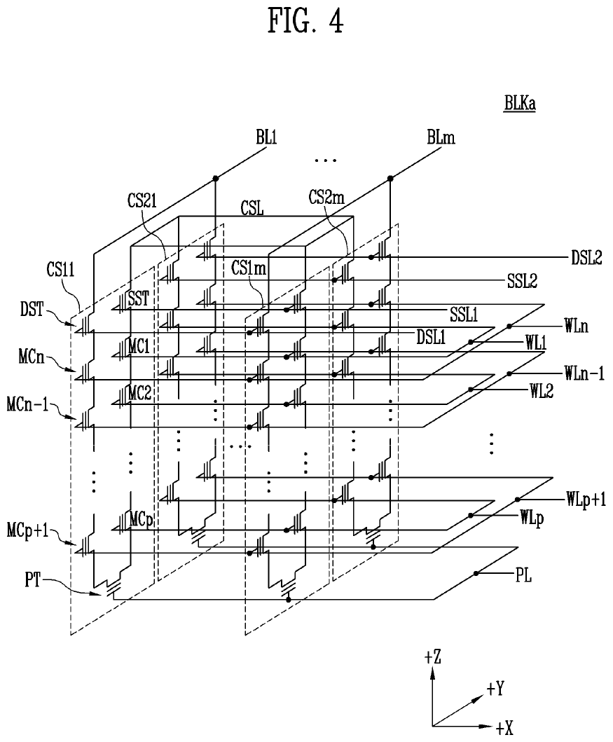

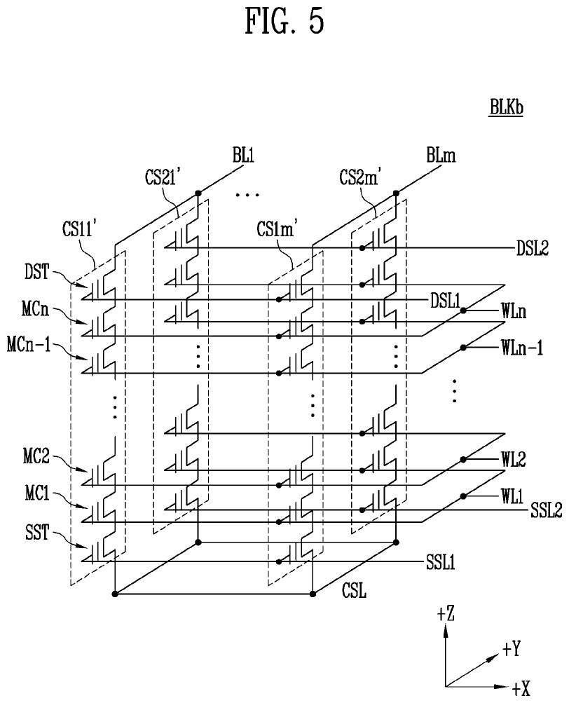

Referring to FIG. 3, the memory cell array 110 includes a plurality of memory blocks BLK1 to BLKz. Each memory block may have a three-dimension& structure. Each memory block includes a plurality of memory cells stacked on a substrate. The plurality of memory cells are arranged along a +X direction, a +Y direction, and a +Z direction. A structure of each memory block is described in more detail with reference to FIGS. 4 and 5.

FIG. 4 is a circuit diagram illustrating a memory block BLKa of the memory blocks BLK1 to BLKz of FIG. 3 according to an embodiment of the present disclosure.

Referring to FIG. 4, the memory block BLKa includes a plurality of cell strings CS11 to CS1m and CS21 to CS2m. In an embodiment, each of the plurality of cell strings CS11 to CS1m and CS21 to CS2m may be formed in a ‘U’ shape. In the memory block BLKa, m cell strings are arranged in a row direction (that is, the +X direction). In FIG. 4, two cell strings are arranged in a column direction (that is, the +Y direction). However, this is for convenience of description and it may be understood that three or more cell strings may be arranged in the column direction.

Each of the plurality of cell strings CS11 to CS1m and CS21 to CS2m includes at least one source select transistor SST, first to nth memory cells MC1 to MCn, a pipe transistor PT, and at least one drain select transistor DST.

Each of the select transistors SST and DST and the memory cells MC1 to MCn may have a similar structure. In an embodiment, each of the select transistors SST and DST and the memory cells MC1 to MCn may include a channel layer, a tunneling insulating film, a charge storage film, and a blocking insulating film. In an embodiment, a pillar for providing the channel layer may be provided in each cell string. In an embodiment, a pillar for providing at least one of the channel layer, the tunneling insulating film, the charge storage film, and the blocking insulating film may be provided in each cell string.

The source select transistor SST of each cell string is connected between a common source line CSL and the memory cells MC1 to MCp.

In an embodiment, the source select transistors of the cell strings arranged in the same row are connected to a source select line extending in the row direction, and the source select transistors of the cell strings arranged in different rows are connected to different source select lines. In FIG. 4, the source select transistors of the cell strings CS11 to CS1m of a first row are connected to a first source select line SSL1. The source select transistors of the cell strings CS21 to CS2m of a second row are connected to a second source select line SSL2.

In another embodiment, the source select transistors of the cell strings CS11 to CS1m and CS21 to CS2m may be commonly connected to one source select line.

The first to nth memory cells MC1 to MCn of each cell string are connected between the source select transistor SST and the drain select transistor DST.

The first to n-th memory cells MC1 to MCn may be divided into first to p-th memory cells MC1 to MCp and (p+1)-th to n-th memory cells MCp+1 to MCn. The first to p-th memory cell, MC1 to MCp are sequentially arranged in a direction opposite to the +Z direction, and are connected in series between the source select transistor SST and the pipe transistor PT. The (p+1)-th to n-th memory cells MCp+1 to MCn are sequentially arranged in the +Z direction, and are connected in series between the pipe transistor PT and the drain select transistor DST. The first to p-th memory cells MC1 to MCp and the (p+1)-th to n-th memory cells MCp+1 to MCn are connected to each other through the pipe transistor PT. Gates of the first to nth memory cells MC1 to MCn of each cell string are connected to the first to n-th word lines WL1 to WLn, respectively.

A gate of the pipe transistor PT of each cell string is connected to a pipeline PL.

The drain select transistor DST of each cell string is connected between a corresponding bit line and the memory cells MCp+1 to MCn. The cell strings arranged in the row direction are connected to the drain select line extending in the row direction. The drain select transistors of the cell strings CS11 to CS1m of the first row are connected to a first drain select line DSL1. The drain select transistors of the cell strings CS21 to CS2m of the second row are connected to a second drain select line DSL2.

The cell strings arranged in the column direction are connected to the hit lines extending in the column direction. In FIG. 4, the cell strings CS11 and CS21 of the first column are connected to the first bit line BL1. The cell strings CS1m and CS2m of the m-th column are connected to the m-th bit line BLm.

The memory cells connected to the same word line in the cell strings arranged in the row direction configure one page. For example, the memory cells connected to the first word line WL1, among the cell strings CS11 to CS1m of the first row configure one page. The memory cells connected to the first word line WL1, among the cell strings CS21 to CS2m of the second row configure another page. The cell strings arranged in one row direction may be selected by selecting one of the drain select lines DSL1 and DSL2. One page of the selected cell strings may be selected by selecting one of the word lines WL1 to WLn.

In another embodiment, even bit lines and odd bit lines may be provided instead of the first to m-th bit lines BL1 to BLm. in addition, even-numbered cell strings among the cell strings CS11 to CS1m or CS21 to SC2m arranged in the row direction may be connected to the bit lines, and odd-numbered cell strings among the cell strings CS11 to CS1m or CS21 to CS2m arranged in the row direction may be connected to odd bit lines, respectively.

In an embodiment, at least one of the first to n-th memory cells MC1 to MCn may be used as a dummy memory cell. For example, at least one dummy memory cell is provided to reduce an electric field between the source select transistor SST and the memory cells MC1 to MCp. Alternatively, at least one dummy memory cell is provided to reduce an electric field between the drain select transistor DST and the memory cells MCp+1 to MCn. As more dummy memory cells are provided, reliability of an operation for the memory block BLKa is improved, however, the size of the memory block BLKa increases. As less memory cells are provided, the size of the memory block BLKa may be reduced, however, the reliability of the operation for the memory block BLKa may be reduced.

In order to efficiently control at least one dummy memory cell, each of the dummy memory cells may have a required threshold voltage. Before or after an erase operation for the memory block BLKa, program operations for all or a part of the dummy memory cells may be performed. When the erase operation is performed after the program operation is performed, the dummy memory cells may have the required threshold voltage by controlling a voltage applied to dummy word lines connected to the respective dummy memory cells.

FIG. 5 is a circuit diagram illustrating a memory block BLKb of the memory blocks BLK1 to BLKz of FIG. 3 according to an embodiment of the present disclosure.

Referring to FIG. 5, the memory block BLKb includes a plurality of cell strings CS11′ to CS1m′ and CS21′ to CS2m′. Each of the plurality of cell strings CS11′ to CS1m′ and CS21′ to CS2m′ extends along a +Z direction. Each of the plurality of cell strings CS11′ to CS1m′ and CS21′ to CS2m′ includes at least one source select transistor SST, first to n-th memory cells MC1 to MCn, and at least one drain select transistor DST stacked on a substrate (not shown) under the memory block BLK1′.

The source select transistor SST of each cell string is connected between a common source line CSL and memory cells MC1 to MCn. The source select transistors of the cell strings arranged in the same row are connected to the same source select line. The source select transistors of the cell strings CS11′ to CS1m′ arranged in a first row are connected to a first source select line SSL1. The source select transistors of the cell strings CS21′ to CS2m′ arranged in a second row are connected to a second source select line SSL2. In another embodiment, the source select transistors of the cell strings CS11′ to CS1m′ and CS21′ to CS2m′ may be commonly connected to one source select line.

The first to nth memory cells MC1 to MCn of each cell string are connected in series between the source select transistor SST and the drain select transistor DST. Gates of the first to n-th memory cells MC1 to MCn are connected to first to the nth word lines WL1 to WLn, respectively,

The drain select transistor DST of each cell string is connected between a corresponding bit line and the memory cells MC1 to MCn. The drain select transistors of the cell strings arranged in the row direction are connected to a drain select line extending in the row direction. The drain select transistors of the cell strings CS11′ to CS1m′ of a first row are connected to a first drain select line DSL1. The drain select transistors of the cell strings CS21′ to CS2m′ of a second row are connected to a second drain select line DSL2.

As a result, the memory block BLKb of FIG. 5 has an equivalent circuit similar to that of the memory block BLKa of FIG. 4 except that the pipe transistor PT is excluded from each cell string.

In another embodiment, even bit lines and odd bit lines may be provided instead of the first to m-th bit lines BL1 to BLm. In addition, even-numbered cell strings among the cell strings CS11′ to CS1m′ or CS21′ to CS2m′ arranged in the row direction may be connected to even bit lines, and odd-numbered cell strings among the cell strings CS11′ to CS1m′ or CS21′ to CS2m′ arranged in the row direction may be connected to odd bit lines, respectively.

In an embodiment, at least one of the first to n-th memory cells MC1 to MCn may be used as a dummy memory cell. For example, at least one dummy memory cell is provided to reduce an electric field between the source select transistor SST and the memory cells MC1 to MCn. Alternatively, at least one dummy memory cell is provided to reduce an electric field between the drain select transistor DST and the memory cells MC1 to MCn. As more dummy memory cells are provided, reliability of an operation for the memory block BLKb is improved, however, the size of the memory block BLKb increases. As less memory cells are provided, the size of the memory block BLKb may be reduced, however, the reliability of the operation for the memory block BLKb may be reduced.

In order to efficiently control at least one dummy memory cell, each of the dummy memory cells may have a required threshold voltage. Before or after an erase operation for the memory block BLKb, program operations for all or a part of the dummy memory cells may be performed. When the erase operation is performed after the program operation is performed, the dummy memory cells may have the required threshold voltage by controlling a voltage applied to the dummy word lines connected to the respective dummy memory cells.

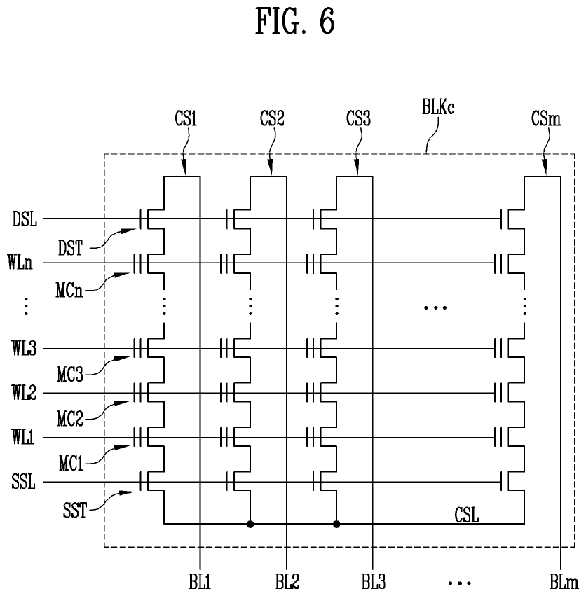

FIG. 6 is a circuit diagram illustrating a memory block BLKc of the memory blocks BLK1 to BLKz included in the memory cell array 110 of FIG. 2 according to an embodiment of the present disclosure.

Referring to FIG. 6, the memory block BLKc includes a plurality of cell strings CS1 to CSm. The plurality of cell strings CS1 to CSm may be connected to a plurality of bit lines BL1 to BLm, respectively. Each of the cell strings CS1 to CSm includes at least one source select transistor SST, first to nth memory cells MC1 to MCn, and at least one drain select transistor DST.

Each of the select transistors SST and DST and the memory cells MC1 to MCn may have a similar structure. In an embodiment, each of the select transistors SST and DST and the memory cells MC1 to MCn may include a channel layer, a tunneling insulating film, a charge storage film, and a blocking insulating film. In an embodiment, a pillar for providing the channel layer may be provided in each cell string. In an embodiment, a pillar for providing at least one of the channel layer, the tunneling insulating film, the charge storage film, and the blocking insulating film may be provided in each cell string,

The source select transistor SST of each cell string is connected between a common source line CSL and the memory cells MC1 to MCn.

The first to n-th memory cells MC1 to MCn of each cell string are connected between the source select transistor SST and the drain select transistor DST.

The drain select transistor DST of each cell string is connected between a corresponding bit line and the memory cells MC1 to MCn.

Memory cells connected to the same word line configure one page. The cell strings CS1 to CSm may be selected by selecting the drain select line DSL. One page among the selected cell strings may be selected by selecting any of the word lines WL1 to WLn.

In another embodiment, even bit lines and odd bit lines may be provided instead of the first to m-th bit lines BL1 to BLm. Even-numbered cell strings among the cell strings CS1 to CSm may be connected to even bit lines, and odd-numbered cell strings may be connected to odd bit lines, respectively.

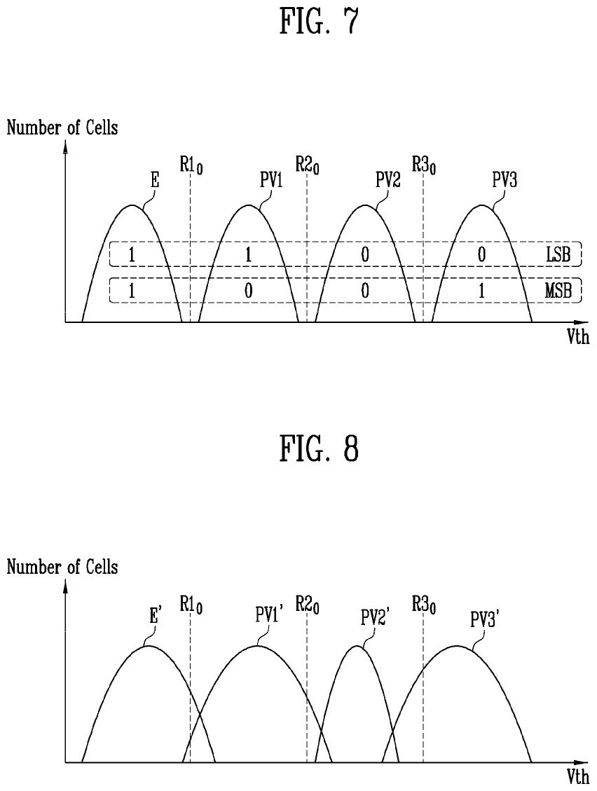

FIG. 7 is a graph illustrating a threshold voltage distribution of a multi-level cell (MLC) according to an embodiment of the present disclosure. The present disclosure may be applied to not only the MLC, but also a single-level cell (SCL), a triple-level cell (TLC), a quad-level cell (QLC), and the like. However, for convenience, a description is given based on the MLC. Referring to FIG. 7, an embodiment in which four threshold voltage states are mapped according to a logic code is shown. According to the example of FIG. 7, a memory cell in which a least significant bit (LSB) is 1 and a most significant bit (MSB) is 1 maintains an erase state E. A memory cell in which the LSB is 1 and the MSB is 0 is programmed to a first program state PV1. A memory cell in which the LSB is 0 and the MSB is 0 is programmed to a second program state PV2. A memory cell in which the LSB is 0 and the MSB is 1 is programmed to a third program state PV3. That is, the logical code shown in FIG. 7 maps data of “1 1” to the erase state E, data of “1 0” to the first program state PV1, data of “0 0” to the second program state PV2, and data of “0 1” to the third program state PV3, based on an LSB-MSB order. However, this is an example, and various logic codes different from that shown in FIG. 7 may be used.

In the example of FIG. 7, first to third read voltages R1₀, R2₀, and R3₀ may be used for the read operation on the MLC. That is, memory cells each having a threshold voltage lower than the first read voltage R1₀ may be determined as the memory cells of the erase state E, memory cells each having a threshold voltage higher than the first read voltage R1₀ and lower than the second read voltage R2₀ may be determined as the memory cells of the first program state PV1. Memory cells each having a threshold voltage higher than the second read voltage R2₀ and lower than the third read voltage R3₀ may be determined as the memory cells of the second program state PV2, and memory cells each having a threshold voltage higher than the third read voltage R3₀ may be determined as the memory cells of the third program state PV3.

In the present specification, a set of the read voltages used to read the data stored in the memory cells included in one page may be referred to as a “read voltage set”. For example, as shown in FIG. 7, in order to read the data stored in the MLC, the first to third read voltages R1₀, R2₀, and R3₀ may be required. That is, the read voltage set for reading the data stored in the MLC may include the first to third read voltages R1₀, R2₀, and R3₀. Similarly, a read voltage set for reading data stored in the TLC may include first to seventh read voltages, and a read voltage set for reading data stored in the QLC may include first to fifteenth read voltages.

FIG. 8 is a graph illustrating a read voltage set which is changed when there is a change of a threshold voltage distribution of memory cells according to an embodiment of the present disclosure.

Referring to FIG. 8, a state in which the threshold voltage distribution of the memory cells is changed after a predetermined time is elapsed after the program operation is completed, is shown. Immediately after the program operation is completed, as shown in FIG. 7, the threshold voltage distribution of each of the states E, PV1, PV2, and PV3 may be formed to be narrow. However, as shown in FIG. 8, when a predetermined time has elapsed after the program operation is completed, the threshold voltage distribution state of the memory cells may be changed. That is, the threshold voltage distribution of the erase state E and the first to third program states PV1 to PV3 shown in FIG. 7 may be changed to a threshold voltage distribution of an erase state E′ and first to third program states PV1′ to PV3′. In a case of FIG. 8, the threshold voltage distribution may be deteriorated compared to that of FIG. 7, and thus an error may occur in the read operation. When reading the data of the memory cells having the threshold voltage distribution shown in FIG. 8 by using the first to third read voltages R1₀ to R3₀ used for the read operation in FIG. 7, a plurality of error bits may be included the read data. In this case, when an error correction operation is performed on the read data, a case where error correction is impossible occurs. Accordingly, at least one read voltage may be required to be changed among the read voltages included in the read voltage set for a data read.

A deterioration aspect of the threshold voltage distribution of the memory cells does not appear in only one way. That is, in order to perform the read operation without failure, one of the read voltages included in the read voltage set may be required to be increased, and another read voltage may be required to be decreased.

In accordance with a controller and a method of operating the same according to an embodiment of the present disclosure, when the read voltage of the read voltage set is changed after the error correction for the read data has failed, the number of memory cells each having a threshold voltage lower than each read voltage is counted based on the read data. In accordance with a controller and a method of operating the same according to an embodiment of the present disclosure, at least one read voltage among the read voltages included in the read voltage set is changed based on the counted number of memory cells. Accordingly, the read voltage may be quickly and efficiently changed.

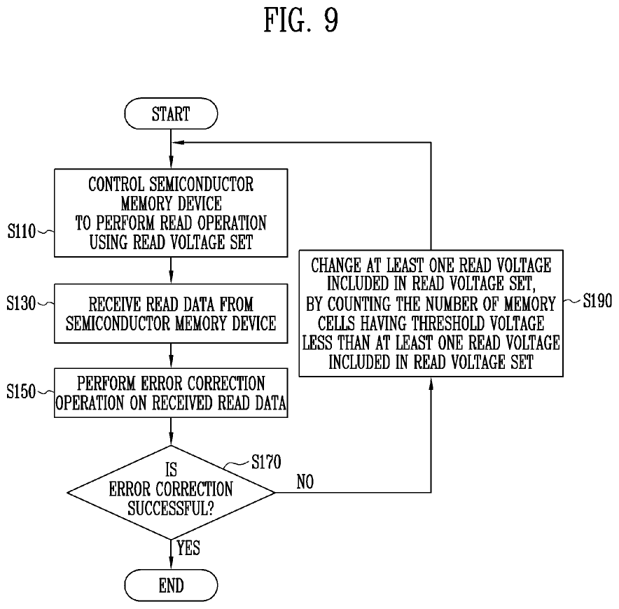

FIG. 9 is a flowchart illustrating a method of operating a controller according to an embodiment of the present disclosure.

Referring to FIG. 9, the method of operating the controller includes controlling the semiconductor memory device to perform the read operation using the read voltage set (S110), receiving the read data from the semiconductor memory device (S130), performing the error correction operation on the received read data (S150), determining whether the error correction is successful (S170), and when error correction has failed (S170: No), changing at least one read voltage included in the read voltage set, by counting the number of memory cells each having a threshold voltage lower than the at least one read voltage included in the read voltage set (S190).

In operation S110, the controller 200 may transmit an address corresponding to a page selected as a read target and a read command for reading data stored in memory cells included in the selected page to the semiconductor memory device 100. The semiconductor memory device 100 may perform a read operation on the memory cells included in the page corresponding to the address, in response to the received read command. The semiconductor memory device 100 may transmit the read data generated by the read operation to the controller 200. Accordingly, the controller 200 receives the read data from the semiconductor memory device 100 (S130).

In operation S150, the error correction block 230 of the controller 200 may perform the error correction operation on the received read data. When the error correction operation is successful (S170: Yes), the read operation may be ended,

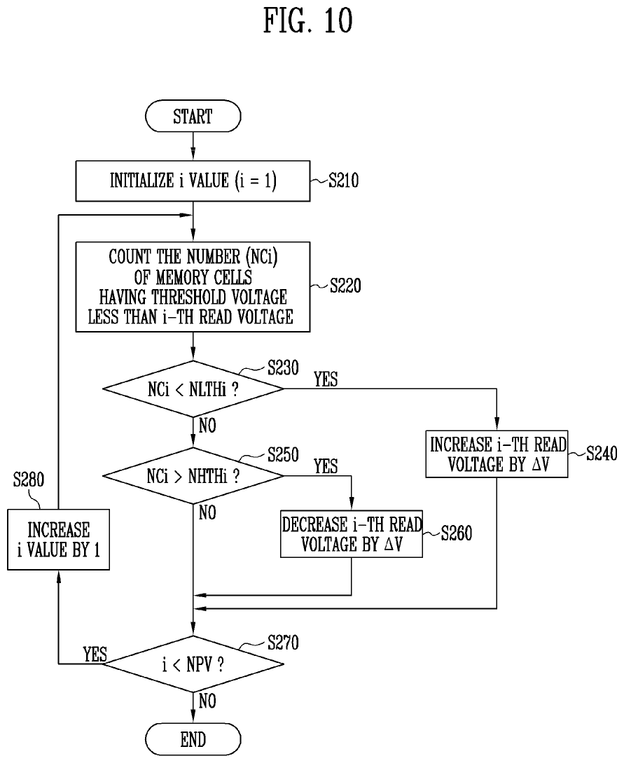

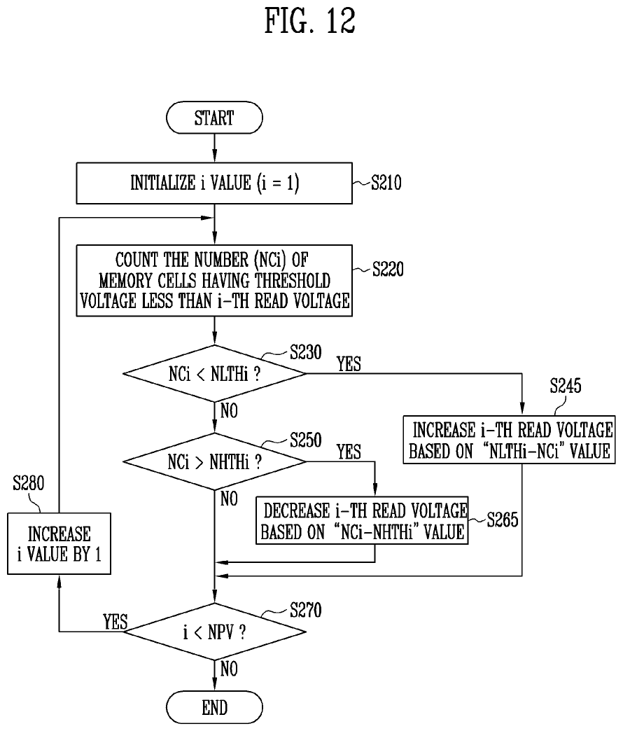

When the error correction operation is failed (S170: No), in operation S190, the memory cell counter 250 may count the number of memory cells each having the threshold voltage lower than the at least one read voltage included in the read voltage set, and the read voltage controller 210 may change the at least one read voltage included in the read voltage set based on a count result. Thereafter, the controller 200 may control the semiconductor memory device 100 to perform the read operation using the read voltage set including the changed read voltage (S110). Specific embodiments of operation S190 are described later with reference to FIGS. 10 and 12.

Referring to FIG. 9, operations S110, S130, S150, S170, and S190 may be repeatedly performed until the error correction operation is successful. When the error correction operation is repeatedly failed, in order to prevent infinite repetition of operations S110, S130, S150, S170, and S190 of FIG. 9, when the read voltage is changed a predetermined number of times, that is, when operation S190 is performed a predetermined number of times, the read operation may be ended even though the error correction operation has failed as a result of the determination of operation S170.

FIG. 10 is a flowchart illustrating an embodiment of operation S190 of FIG. 9.

Referring to FIG. 10, first, an ‘i’ value is initialized in operation S210. The ‘i’ value may be a number indicating a read voltage that is a target for determining whether to change, among the plurality of read voltages included in the read voltage set. As described above, the first to third read voltages may be used for the read operation of the MLC. Accordingly, in a case of the read operation of the MLC, the ‘i’ value may be 1 to 3. Therefore, in operation S210, the ‘i’ value may be initialized to 1.

In operation S220, the number of memory cells NCi having a threshold voltage lower than an i-th read voltage is counted. Since the ‘i’ value is currently 1 the number NC1 of memory cells each having a threshold voltage lower than the first read voltage R1₀ is counted.

The number NC1 of memory cells each having the threshold voltage lower than the first read voltage R1₀ may be obtained by counting the number of a bit-pair in which the LSB and MSB are “1 1” respectively in the read data received from the semiconductor memory device. That is, when counting the number of elements of an intersection of columns in which a bit value is “1” in an LSB page data of the read data and columns in which a bit value is “1” in an MSB page data, the number NC1 of memory cells each having the threshold voltage lower than the first read voltage R1₀ may be calculated.

For example, the number of memory cells included in a read target page is 400. Through data randomizing, the number of memory cells included in each threshold voltage state is almost the same. That is, the number of memory cells belonging to each of the erase state E and the first to third program states PV1 to PV3 may become 100.

Referring back to FIG. 7, when the number of memory cells of the erase state E is 100 and the number of memory cells belonging to each of the first to third program states PV1 to PV3 is 100, the number of memory cells each having the threshold voltage lower than the first read voltage R1₀ may be 100. As shown in FIG. 8, when the number of memory cells each having the threshold voltage lower than the first read voltage R1₀ is relatively less than 100, increasing the first read voltage R1₀ helps in increasing accuracy of a subsequent read operation. Conversely, when the number of memory cells each having the threshold voltage lower than the first read voltage R1₀ is a greater value than 100, decreasing the first read voltage R1₀ helps in increasing the accuracy of the subsequent read operation,

However, when the number of memory cells each having the threshold voltage lower than the first read voltage R1₀ is not significantly different from 100 as a result of the read, not changing the first read voltage R1₀ may be more helpful in increasing the accuracy of the subsequent read operation. For example, when the number of memory cells each having the threshold voltage lower than the first read voltage R1₀ is 98 or 99, the first read voltage R1₀ may be substantially in the vicinity of a valley formed by the erase state E′ and the program state PV1′. Therefore, in this case, not changing the first read voltage may help in increasing the accuracy of the subsequent read operation.

Therefore, in accordance with the controller 200 and the method of operating the same according to an embodiment of the present disclosure, when the number of memory cells each having a threshold voltage lower than the i-th read voltage is less than a lower threshold value NLTHi or greater than an upper threshold value NHTHi, the i-th read voltage is changed.

For example, in an example in which the number of memory cells of the erase state E is 100 and the number of memory cells belonging to each of the first to third program states PV1 to PV3 is 100, a lower threshold value NLTH1 corresponding to the first read voltage may have a value of 90, which is less than 100 by 10, and an upper threshold value NHTH1 may have a value of 110, which is greater than 100 by 10.

In operation S230 of FIG. 10, it is determined whether the number NC1 of memory cells each having the threshold voltage lower than the first read voltage R1₀ is less than the first lower threshold value NLTH1, for example 90. When the number NC1 of memory cells each having the threshold voltage lower than the first read voltage R1₀ is less than the first lower threshold value NLTH1 (S230: Yes), the first read voltage is increased by a predetermined voltage value ΔV (S240).

When the number NC1 of memory cells each having the threshold voltage lower than the first read voltage R1₀ is not less than the first lower threshold value NLTH1 (S230: No), the method proceeds to operation S250 to determine whether the number NC1 of memory cells each having the threshold voltage lower than the read voltage R1₀ is greater than the first upper threshold value NHTH1, for example 110. When the number NC1 of memory cells each having the threshold voltage lower than the first read voltage R1₀ is greater than the first upper threshold value NHTH1 (S250: Yes), the first read voltage is decreased by the predetermined voltage value ΔV (S260).

Referring to operations S230, S240, S250, and S260 of FIG. 10, when the number NC1 of memory cells each having the threshold voltage lower than the first read voltage R1₀ is less than the first lower threshold value NLTH1, the first read voltage is increased by the predetermined voltage value ΔV (S240), and when the number NC1 of memory cells each having the threshold voltage lower than the first read voltage R1₀ is greater than or equal to the first lower threshold value NLTH1 and less than or equal to the first upper threshold value NHTH1, the first read voltage is not changed. On the other hand, when the number NC1 of memory cells each having the threshold voltage lower than the first read voltage R1₀ is greater than the first upper threshold value NHTH1, the first read voltage is decreased by the predetermined voltage value ΔV (S260). Accordingly, when the number NC1 of memory cells each having the threshold voltage lower than the first read voltage R1₀ has a difference of 10 or more based on 100, which is an example ideal value, the first read voltage is changed.

Thereafter, in operation S270, it is determined whether the current ‘i’ value is less than the number NPV of the read voltages in the read voltage set. In a case of the MLC, the NPV value is 3. In a case of the TLC, the NPV value is 7. In a case of the QLC, the NPV value is 15. Since the current ‘i’ value is 1 which is less than 3, the method proceeds to operation S280 to increase the T value to 2. Thereafter, the method proceeds to operation S220 to perform operations S220, S230, S240, S250, and S260 on the second read voltage R2₀. That is, when the number NC2 of memory cells each having a threshold voltage lower than the second read voltage R2₀ is less than a second lower threshold value NLTH2, the second read voltage is increased by the predetermined voltage value ΔV (S240), and when the number NC2 of memory cells each having the threshold voltage lower than the second read voltage R2₀ is greater than or equal to the second lower threshold value NLTH2 and less than or equal to a second upper threshold value NHTH2, the second read voltage is not changed. When the number NC2 of memory cells each having the threshold voltage lower than the second read voltage R2₀ is greater than the second upper threshold value NHTH2, the second read voltage is decreased by the predetermined voltage value ΔV (S260). Accordingly, when the number NC2 of memory cells each having the threshold voltage lower than the second read voltage R2₀ has a difference of 10 or more based on 200, which is an example ideal value, the first read voltage is changed.

Thereafter, a similar operation may be performed on the third read voltage. In an example in which the number of memory cells of the erase state E is 100 and the number of memory cells belonging to each of the first to third program states PV1 to PV3 is 100, an example in which the first lower and upper threshold values NLTH1 and NHTH1, the second lower and upper threshold values NLTH2 and NHTH2, and third lower and upper threshold values NLTH3 and NHTH3 are in the following Table 1.

TABLE 1

| NLTH1 | NHTH1 | NLTH2 | NHTH2 | NLTH3 | NHTH3 |
|---|---|---|---|---|---|
| 90 | 110 | 190 | 210 | 290 | 310 |

According to the flowchart shown in FIG. 10, operation S190 may be performed. In accordance with the controller and the method of operating the same according to an embodiment of the present disclosure, the semiconductor memory device 100 may be controlled to perform the read operation using the changed read voltage set thereafter (S110). When the error correction operation has failed again (S170: No), operation S190 may be performed again.

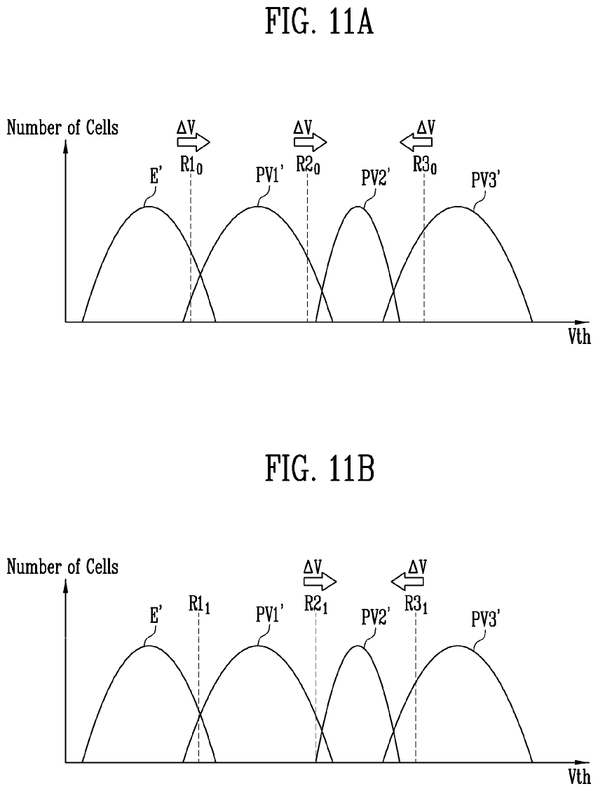

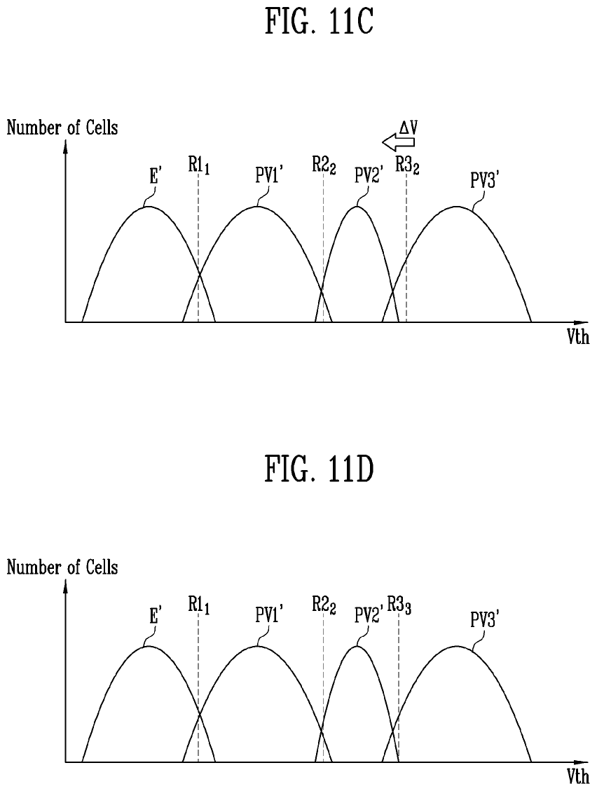

FIGS. 11A, 11B, 11C, and 11D are graphs illustrating a method of changing a read voltage of FIG. 10 according to an embodiment of the present disclosure.

Referring to FIG. 11A, the number NC1 of memory cells each having the threshold voltage lower than the first read voltage R1₀ is less than the first lower threshold value NLTH1, the number NC2 of memory cells each having the threshold voltage lower than the second read voltage R2₀ is less than the second lower threshold value NLTH2, and the number NC3 of memory cells each having a threshold voltage lower than the third read voltage R3₀ is greater than a third upper threshold value NLTH3. Accordingly, the first read voltage R1₀ and the second read voltage R2₀ are increased by the predetermined voltage value ΔV (S240), and the third read voltage R3₀ is decreased by the predetermined voltage value ΔV (S260).

Referring to FIG. 11B, changed first to third read voltages R1₁, R2₁, and R3₁ are shown. When the error correction operation has failed as a result of performing the read operation again using the first to third read voltages R1₁, R2₁, and R3₁ (S170: No), operations shown in FIG. 10 may be performed again. Referring to FIG. 11B, the number NC1 of memory cells each having a threshold voltage lower than the changed first read voltage R1₁ is greater than or equal to the first lower threshold value NLTH1 and is less than or equal to the first upper threshold value NHTH1. Accordingly, the first read voltage R1₁ is not changed again. Referring to FIG. 11B, the number NC2 of memory cells each having a threshold voltage lower than the second read voltage R21 is less than the second lower threshold value NLTH2, and the number NC3 of memory cells each having a threshold voltage lower than the third read voltage R3₁ is greater than the third upper threshold value NLTH3. Accordingly, the second read voltage R2₁ is increased by the predetermined voltage value ΔV (S240), and the third read voltage R3₁ is decreased by the predetermined voltage value ΔV (S260).

Referring to FIG. 11C, the first read voltage R1₁ and the changed second and third read voltages R2₂ and R3₂ are shown. When the error correction operation has failed as a result of performing the read operation again using the first to third read voltages R1₁, R2₂, and R3₂ (S170: No), operations shown in FIG. 10 may be performed again. Referring to FIG. 11C, the number NC1 of memory cells each having the threshold voltage lower than the first read voltage R1₁ is greater than or equal to the first lower threshold value NLTH1 and is less than or equal to the first upper threshold value NHTH1. Accordingly, the first read voltage R1₁ is not changed again. In addition, the number NC2 of memory cells each having the threshold voltage lower than the changed second read voltage R2₂ is greater than or equal to the second lower threshold value NLTH2 and is less than or equal to the second upper threshold value NHTH2. Accordingly, the second read voltage R2₂ is not changed again. Referring to FIG. 11C, the number NC3 of memory cells each having a threshold voltage lower than the changed third read voltage R3₂ is greater than the third upper threshold value NLTH3. Accordingly, the third read voltage R3₂ is decreased by the predetermined voltage value ΔV (S260).

Referring to FIG. 11D, the first read voltage R1₁, the second read voltage R2₂, and a changed third read voltage R3₃ are shown. When the error correction operation has failed as a result of performing the read operation again using the first to third read voltages R1₁, R2₂, and R3₃ (S170: No), operations shown in FIG. 10 may be performed again. Referring to FIG. 11D, the number NC1 of memory cells each having the threshold voltage lower than the first read voltage Rh is greater than or equal to the first lower threshold value NLTH1 and is less than or equal to the first upper threshold value NHTH1. Accordingly, the first read voltage R1₁ is not changed again. In addition, the number NC2 of memory cells each having the threshold voltage lower than the second read voltage R2₂ is greater than or equal to the second lower threshold value NLTH2 and is less than or equal to the second upper threshold value NHTH2. Accordingly, the second read voltage R2₂ is not changed again. The number NC3 of memory cells each having the threshold voltage lower than the changed third read voltage R3₃ is greater than or equal to the third lower threshold value NLTH3 and is less than or equal to the third upper threshold value NHTH3. Accordingly, the third read voltage R3₃ is not changed again. Therefore, the read voltage set is not changed, and thus the entire read operation may be ended.

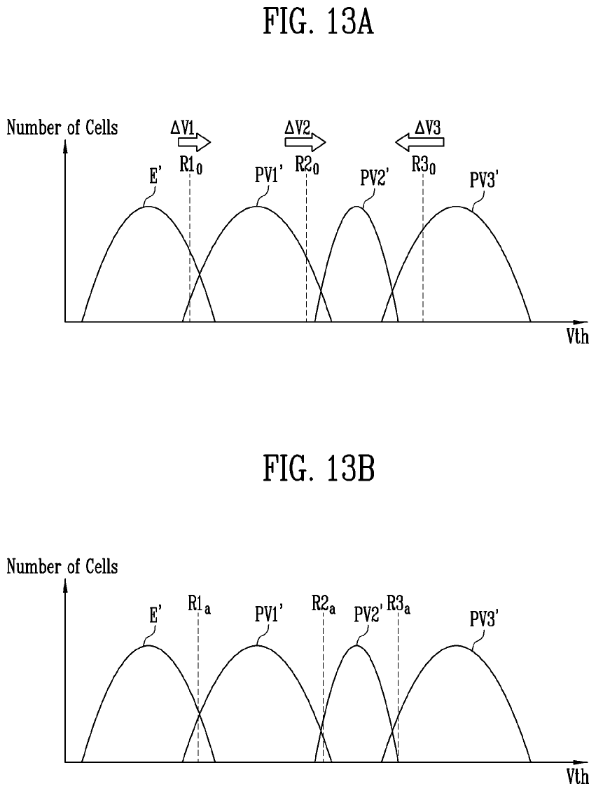

Referring back to FIGS. 10 and 11A to 11D, when the number NCi of memory cells each having the threshold voltage lower than the i-th read voltage outside a predetermined range, that is, a range (defined as the i-th lower threshold value NLTHi and the i-th upper threshold value NHTHi, the i-th read voltage is changed. At this time, according to the embodiment shown in FIGS. 10 and 11A to 11D, the i-th read voltage is changed by the predetermined voltage value ΔV (S240 or S260) regardless of a degree at which NCi deviates out of the range NLTHi to NHTHi. In another embodiment, in order to more accurately change the read voltage, a change degree of the i-th read voltage may be determined according to the degree at which the NCi deviates out of the range NLTHi to NHTHi. The above-described embodiment is described with reference to FIGS. 12, 13, and 13B.

FIG. 12 is a flowchart illustrating another embodiment of operation S190 of FIG. 9 according to an embodiment of the present disclosure. Other operations S210, S220, S230, S250, S270, and S280 of FIG. 12 may be the same as described with reference to FIG. 10 except that operations S240 and S260 of FIG. are replaced by operations S245 and S265 in FIG. 12, respectively. Therefore, a repetitive description is omitted.

Referring to FIG. 12, first, in operation 5210, the ‘i’ value is initialized. In operation S220, the number NCi of memory cells each having the threshold voltage lower than the i-th read voltage is counted. Since the ‘i’ value is currently 1, the number NC1 of memory cells each having the threshold voltage lower than the first read voltage R1₀ is counted.

In operation S230, it is determined whether the number NC1 of memory cells each having the threshold voltage lower than the first read voltage R1₀ is less than the first lower threshold value NLTH1, for example 90. When the number NC1 of memory cells each having the threshold voltage lower than the first read voltage R1₀ is less than the first lower threshold value NLTH1 (S230: Yes), the first read voltage is increased based on the difference between the first lower threshold value NLTH1 and the number NC1 of memory cells each having the threshold voltage lower than the first read voltage R1₀, that is, “NLTH1-NC1” value (S245).

When the “NLTH1-NC1” value is relatively large, this means that a degree at which the number NC1 of memory cells each having the threshold voltage lower than the first read voltage R1₀ deviates from the first lower threshold value NLTH1 is relatively large. Therefore, in this case, a relatively large increase width of the first read voltage R1₀ may be applied.

When the “NLTH1-NC1” value is relatively small, this means that the degree at which the number NC1 of memory cells each having the threshold voltage lower than the first read voltage R1₀ deviates from the first lower threshold value NLTH1 is relatively small. Therefore, in this case, a relatively small increase width of the first read voltage R1₀ may be applied.

That is, in operation 5245, the first read voltage may be increased by a value corresponding to the degree at which the number NC1 of memory cells each having the threshold voltage lower than the first read voltage R1₀ deviates from the first lower threshold value NLTH1.

When the number NC1 of memory cells each having the threshold voltage lower than the first read voltage R1₀ is not less than the first lower threshold value NLTH1 (S230: No), the method proceeds to determine whether the number NC1 of memory cells each having the threshold voltage lower than the first read voltage R1₀ is greater than the first upper threshold value NHTH1, for example, 110. When the number NC1 of memory cells each having the threshold voltage lower than the first read voltage R1₀ is greater than the first upper threshold value NHTH1 (S250: Yes), the first read voltage is decreased based on the difference between the first upper threshold value NHTH1 and the number NC1 of memory cells each having the threshold voltage lower than the first read voltage R1₀, that is, “NC1-NHTH1” value (S265).

When the “NC1-NHTH1” value is relatively large, this means that a degree at which the number NC1 of memory cells each having the threshold voltage lower than the first read voltage R1₀ deviates from the first upper threshold value NHTH1 is relatively large. Therefore, in this case, a relatively large decrease width of the first read voltage R1₀ may be applied.

When the “NC1-NHTH1” value relatively small, this means that the degree at which the number NC1 of memory cells each having the threshold voltage lower than the first read voltage R1₀ deviates from the first upper threshold value NHTH1 is relatively small. Therefore, in this case, a relatively small decrease width of the first read voltage R1₀ may be applied.

That is, in operation S265, the first read voltage may be decreased by a value corresponding to the degree at which the number NC1 of memory cells each having the threshold voltage lower than the first read voltage R1₀ deviates from the first upper threshold value NHTH1.

FIGS. 13A and 13B are graphs illustrating a method of changing a read voltage of FIG. 12 according to an embodiment of the present disclosure.

Referring to FIG. 13A, the number NC1 of memory cells each having the threshold voltage lower than the first read voltage R1₀ is less than the first lower threshold value NLTH1, the number NC2 of memory cells each having the threshold voltage lower than the second read voltage R2₀ is less than the second lower threshold value NLTH2, and the number NC3 of memory cells NC3 having the threshold voltage lower than the third read voltage R3₀ is greater than the third upper threshold value NLTH3. Accordingly, the first read voltage R1₀ and the second read voltage R2₀ are increased (S245), and the third read voltage R3₀ is decreased (S265).

In FIG. 13A, change widths of the first read voltage R1₀, the second read voltage R2₀, and the third read voltage R3₀ are different from each other. That is, the first read voltage R1₀ is increased by a first voltage ΔV1, the second read voltage R2₀ is increased by a second voltage ΔV2, and the third read voltage R3₀ is decreased by a third voltage ΔV3.

Referring to FIG. 13B, changed first to third read voltages R1ₐ, R2ₐ, and R3ₐ are shown. When the error correction operation has failed as a result of performing the read operation again using the first to third read voltages R1ₐ, R2ₐ, and R3ₐ (S170: No), operations shown in FIG. 10 may be performed again. Referring to FIG. 13B, the number NC1 of memory cells each having a threshold voltage lower than the first read voltage R1ₐ is greater than or equal to the first lower threshold value NLTH1 and less than or equal to the first upper threshold value NHTH1. Accordingly, the first read voltage R1ₐ is not changed again. In addition, the number NC2 of memory cells each having a threshold voltage lower than the second read voltage R2ₐ is greater than or equal to the second lower threshold value NLTH2 and less than or equal to the second upper threshold value NHTH2. Accordingly, the second read voltage R2ₐ is not changed again. The number NC3 of memory cells each having a threshold voltage lower than the third read voltage R3ₐ is greater than or equal to the third lower threshold value NLTH3 and less than or equal to the third upper threshold value NHTH3. Accordingly, the third read voltage R3ₐ is not changed again. Therefore, the read voltage set may not be changed, and thus the entire read operation may he ended,

When comparing FIGS. 13A and 13B with FIGS. 11A to 11D, in a case where the change width of the read voltage is different according to the degree at which the number of memory cells each having the threshold voltage lower than the read voltage deviates from the lower threshold value or the upper threshold value, the read operation may be performed more efficiently. That is, according to the embodiments shown in FIGS. 12, 13A, and 13B, an optimum read voltage in the read voltage set may be set faster than the embodiments shown in FIGS. 10 and 11A to 11D. Accordingly, a read speed by the semiconductor memory device 100 and the controller 200 may be improved.

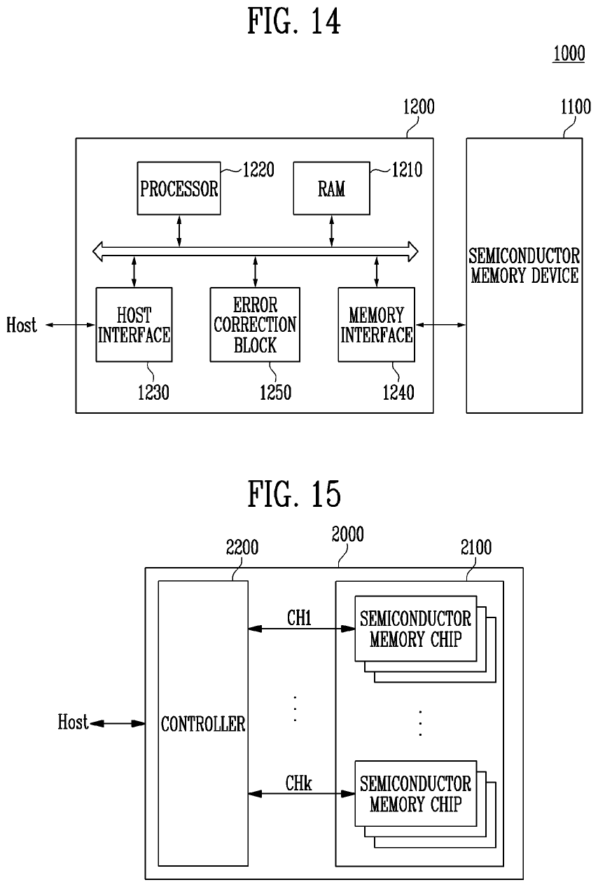

FIG. 14 is a block diagram illustrating a memory system 1000 including the controller of FIG. 1 according to an embodiment of the present disclosure.

Referring to FIG. 14, the memory system 1000 includes the semiconductor memory device 1100 and the controller 1200. The semiconductor memory device 1100 may be the semiconductor memory device described with reference to FIG. 2. Hereinafter, a repetitive description is omitted.

The controller 1200 is connected to a host Host and the semiconductor memory device 1100. The controller 1200 is configured to access the semiconductor memory device 1100 in response to a request from the host Host. For example, the controller 1200 is configured to control read, write, erase, and background operations of the semiconductor memory device 1100. The controller 1200 is configured to provide an interface between the semiconductor memory device 1100 and the host Host. The controller 1200 is configured to drive firmware for controlling the semiconductor memory device 1100. The controller 1200 may be the controller 200 described with reference to FIG. 1.

The controller 1200 includes a random access memory (RAM) 1210, a processor 1220, a host interface 1230, a memory interface 1240, and an error correction block 1250. The RAM 1210 is used as at least one of an operation memory of the processor 1220, a cache memory between the semiconductor memory device 1100 and the host Host, and a buffer memory between the semiconductor memory device 1100 and the host Host. In addition, the controller 1200 may temporarily store program data provided from the host Host during the write operation.

The processor 1220 controls an overall operation of the controller 1200. The processor 1220 may execute firmware loaded by the RAM 1210. The read voltage controller 210 and the memory cell counter 250 shown in FIG. 1 may be implemented as firmware executed by the processor 1220.

The host interface 1230 includes a protocol for performing data exchange between the host Host and the controller 1200. In an embodiment, the controller 1200 is configured to communicate with the host Host through at least one of various communication standards or interfaces such as a universal serial bus (USB) protocol, a multimedia card (MMC) protocol, a peripheral component interconnection (PCI) protocol, a PCI-express (PCI-E) protocol, an advanced technology attachment (ATA) protocol, a serial ATA protocol, a parallel ATA protocol, a small computer system interface (SCSI) protocol, an enhanced small disk interface (ESDI) protocol, an integrated drive electronics (IDE) protocol, and a private protocol.

The memory interface 1240 interfaces with the semiconductor memory device 1100. For example, the memory interface 1240 includes a NAND interface or a NOR interface.

The error correction block 1250 is configured to detect and correct an error of data received from the semiconductor memory device 1100 using an error correcting code (ECC). The processor 1120 may control the semiconductor memory device 1100 to adjust a read voltage and perform re-read according to an error detection result of the error correction block 1250. In an embodiment, the error correction block may be provided as a component of the controller 1200. The error correction block 230 of FIG. 1 may be substantially the same component as the error correction block 1250 of FIG. 14.

The controller 1200 and the semiconductor memory device 1100 may be integrated into one semiconductor device. In an embodiment, the controller 1200 and the semiconductor memory device 1100 may be integrated into one semiconductor device to form a memory card. For example, the controller 1200 and the semiconductor memory device 1100 may be integrated into one semiconductor device to form a memory card such as a PC card (personal computer memory card international association (PCMCIA)), a compact flash card (CF), a smart media card (SM or SMC), a memory stick, a multimedia card (MMC, RS-MMC, or MMCmicro), an SD card (SD, miniSD, microSD, or SDHC), and a universal flash storage (UFS).

The controller 1200 and the semiconductor memory device 1100 may be integrated into one semiconductor device to form a semiconductor drive (solid state drive (SSD)). The semiconductor drive (SSD) includes a storage device configured to store data in a semiconductor memory. When the memory system 1000 is used as the semiconductor drive (SSD), an operation speed of the host connected to the memory system 1000 is dramatically improved.

As another example, the memory system 1000 is provided as one of various components of an electronic device such as a computer, an ultra-mobile PC (UMPC), a workstation, a net-book, a personal digital assistants (PDA), a portable computer, a web tablet, a wireless phone, a mobile phone, a smart phone, an e-book, a portable multimedia player (PMP), portable game machine, a navigation device, a black box, a digital camera, a 3-dimensional television, a digital audio recorder, a digital audio player, a digital picture recorder, a digital picture player, a digital video recorder, and a digital video player, a device capable of transmitting and receiving information in a wireless environment, one of various electronic devices configuring a home network, one of various electronic devices configuring a computer network, one of various electronic devices configuring a telematics network, an RFID device, or one of various components configuring a computing system.

In an embodiment, the semiconductor memory device 1100 or the memory system may be mounted as a package of various types. For example, the semiconductor memory device 1100 or the memory system 1000 may be packaged and mounted in a method such as a package on package (PoP), ball grid arrays (BGAs), chip scale packages (CSPs), plastic leaded chip carriers (PLCC), a plastic dual in line package (PDIP), a die in waffle pack, die in wafer form, a chip on board (COB), a ceramic dual in line package (CERDIP), a plastic metric quad flat pack (MQFP), a thin quad flat pack (TQFP), a small outline integrated circuit (SOIC), a shrink small outline package (SSOP), a thin small outline package (TSOP), a system in package (SIP), a multi-chip package (MCP), a wafer-level fabricated package (WFP), or a wafer-level processed stack package (WSP).

FIG. 15 is a block diagram illustrating an application example of the memory system of FIG. 14 according to an embodiment of the present disclosure.

Referring to FIG. 15, the memory system 2000 includes a semiconductor memory device 2100 and a controller 2200. The semiconductor memory device 2100 includes a plurality of semiconductor memory chips. The plurality of semiconductor memory chips are divided into a plurality of groups.

In FIG. 15, the plurality of groups communicate with the controller 2200 through first to k-th channels CH1 to CHk, respectively. Each semiconductor memory chip is configured and is operated similarly to one of the semiconductor memory device 1100 described with reference to FIG. 2.

Each group is configured to communicate with the controller 2200 through one common channel. The controller 2200 is configured similarly to the controller 1200 described with reference to FIG. 14 and is configured to control the plurality of memory chips of the semiconductor memory device 2100 through the plurality of channels CH1 to CHk.

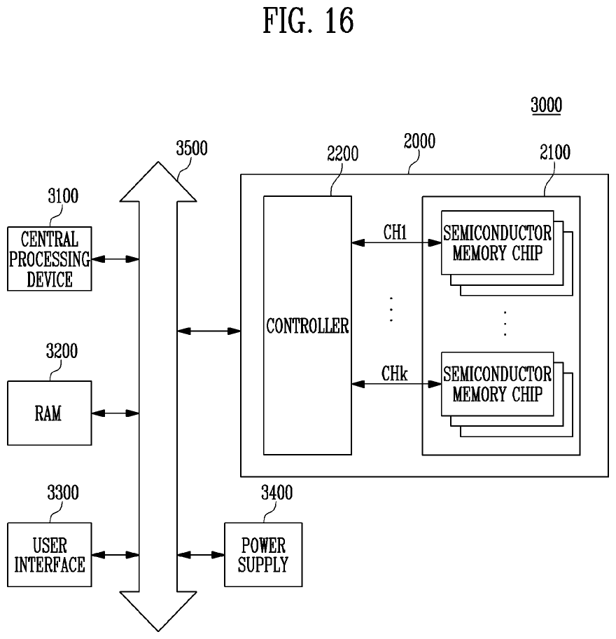

FIG. 16 is a block diagram illustrating a computing system 3000 including the memory system described with reference to FIG. 15 according to an embodiment of the present disclosure.

The computing system 3000 includes a central processing device 3100, a random access memory (RAM) 3200, a user interface 3300, a power supply 3400, a system bus 3500, and the memory system 2000.

The memory system 2000 is electrically connected to the central processing device 3100, the RAM 3200, the user interface 3300, and the power supply 3400 through the system bus 3500. Data provided through the user interface 3300 or processed by the central processing device 3100 is stored in the memory system 2000.

In FIG. 16, the semiconductor memory device 2100 is connected to the system bus 3500 through the controller 2200. However, the semiconductor memory device 2100 may be configured to be directly connected to the system bus 3500. At this time, a function of the controller 2200 is performed by the central processing device 3100 and the RAM 3200.

In FIG. 16, the memory system 2000 described with reference to FIG. 15 is provided. However, the memory system 2000 may be replaced with the memory system 1000 described with reference to FIG. 14. In an embodiment, the computing system 3000 may include both of the memory systems 1000 and 2000 described with reference to FIGS. 14 and 15.

The embodiments of the present disclosure disclosed in the present specification and drawings are merely provided with specific examples to easily describe the technical content of the present disclosure and to help understanding of the present disclosure, and are not intended to limit the scope of the present disclosure. It will be apparent to those of ordinary skill in the art that other modified examples based on the technical spirit of the present disclosure may be implemented in addition to the embodiments disclosed herein.

In the above-described embodiments, all operations may be selectively performed or skipped. In addition, the operations in each embodiment may not always be sequentially performed in given order, and may be randomly performed. Furthermore, the embodiments disclosed in the present specification and the drawings aim to help those with ordinary knowledge in this art to more clearly understand the present disclosure rather than aiming to limit the bounds of the present disclosure. In other words, one of ordinary skill in the art to which the present disclosure belongs will be able to easily understand that various modifications are possible based on the technical scope of the present disclosure and the following claims. Furthermore, the embodiments may be combined to form additional embodiments.

What is claimed is:

1. A method of operating a controller controlling a semiconductor memory device including a plurality of memory cells, the method comprising:
controlling the semiconductor memory device to perform a read operation on selected memory cells among the plurality of memory cells by using a read voltage set including at least one read voltage;
receiving read data from the semiconductor memory device; and
changing at least one read voltage included in the read voltage set by counting, based on the read data, a number of memory cells each having a threshold voltage lower than the at least one read voltage included in the read voltage set.

2. The method of claim 1,
further comprising performing an error correction operation on the received read data,
wherein the changing the at least one read voltage included in the read voltage set is performed in response to a determination that the error correction operation has failed on the received read data.

3. The method of claim 2, further comprising controlling, after the changing the at least one read voltage, the semiconductor memory device to perform the read operation on the selected memory cells among the plurality of memory cells by using the read voltage set including the changed read voltage,

4. The method of claim 1,
wherein the read voltage set includes first to N-th read voltages, where N is a natural number greater than or equal to 1, and
wherein the changing the at least one read voltage included in the read voltage set comprises:
counting the number of memory cells each having the threshold voltage lower than an i-th read voltage among the first to Nth read voltages, where ‘i’ is a natural number greater than or equal to 1 and less than or equal to N;
comparing the number of memory cells each having the threshold voltage lower than the i-th read voltage with an i-th lower threshold value; and
increasing the i-th read voltage in response to a determination that the number of memory cells each having the threshold voltage lower than the i-th read voltage is less than the i-th lower threshold value.

5. The method of claim 4, wherein the increasing the i-th read voltage comprises increasing the i-th read voltage by a predetermined voltage value.

6. The method of claim 4, wherein the increasing the i-th read voltage comprises increasing the i-th read voltage by a voltage value determined according to a difference between the i-th lower threshold value and the number of memory cells each having the threshold voltage lower than the i-th read voltage.

7. The method of claim 1,
wherein the read voltage set includes first to N-th read voltages, where N is a natural number greater than or equal to 1, and
wherein the changing the at least one read voltage included in the read voltage set comprises:
counting the number of memory cells each having the threshold voltage lower than an i-th read voltage among the first to N-th read voltages, where ‘i’ is a natural number greater than or equal to 1 and less than or equal to N;
comparing the number of memory cells each having the threshold voltage lower than the i-th read voltage with an i-th upper threshold value; and
decreasing the i-th read voltage in response to a determination that the number of memory cells each having the threshold voltage lower than the i-th read voltage is greater than the i-th upper threshold.

8. The method of claim 7, wherein the decreasing the i-th read voltage comprises decreasing the i-th read voltage by a predetermined voltage value,

9. The method of claim 7, wherein the decreasing the i-th read voltage comprises decreasing the i-th read voltage by a voltage value determined according to a difference between the number of memory cells each having the threshold voltage lower than the i-th read voltage and the i-th upper threshold value.

10. A controller controlling a semiconductor memory device including a plurality of memory cells, the controller comprising:
a read voltage controller configured to control a magnitude of at least one read voltage included in a read voltage set used during a read operation on selected memory cells among the plurality of memory cells; and
a memory cell counter configured to count, based on read data received from the semiconductor memory device, a number of memory cells each having a threshold voltage lower than the at least one read voltage among the selected memory cells,
wherein the read voltage controller controls the magnitude by changing the at least one read voltage based on a result of the counting.

11. The controller of claim 10,
further comprising an error correction block configured to perform an error correction operation on the received read data,
wherein the memory cell counter counts the number of memory cells each having the threshold voltage lower than the at least one read voltage among the selected memory cells in response to a determination of the error correction block that the error correction operation on the received read data has been failed.

12. The controller of claim 10,
wherein the read voltage set includes first to Nth read voltages, where N is a natural number greater than or equal to 1, and
wherein the memory cell counter counts the number of memory cells each having a threshold voltage lower than an i-th read voltage among first to N-th read voltages, where ‘i’ is a natural number greater than or equal to 1 and less than or equal to N.

13. The controller of claim 12,
wherein the read voltage controller is further configured to compare the number of memory cells each having the threshold voltage lower than the i-th read voltage with an i-th lower threshold value, and
wherein the read voltage controller changes the at least one read voltage by increasing the i-th read voltage in response to a determination that the number of memory cells each having the threshold voltage lower than the i-th read voltage is less than the i-th lower threshold.

14. The controller of claim 13, wherein the read voltage controller increases the i-th read voltage by a predetermined voltage value.

15. The controller of claim 13, wherein the read voltage controller increases the i-th read voltage by a voltage value determined according to a difference between the i-th lower threshold value and the number of memory cells each having the threshold voltage lower than the i-th read voltage,

16. The controller of claim 12,
wherein the read voltage controller further configured to compare the number of memory cells each having the threshold voltage lower than the i-th read voltage with an i-th upper threshold value, and
wherein the read voltage controller changes the at least one read voltage by decreasing the i-th read voltage in response to a determination that the number of memory cells each having the threshold voltage lower than the i-th read voltage is greater than the i-th upper threshold value.

17. The controller of claim 16, wherein the read voltage controller decreases the i-th read voltage by a predetermined voltage value.

18. The controller of claim 16, wherein the read voltage controller decreases the i-th read voltage by a voltage value determined according to a difference between the number of memory cells each having the threshold voltage lower than the i-th read voltage and the i-th upper threshold.

19. An operating method of a controller, the operating method comprising:
controlling a memory device to perform a first read operation on a cell group with a first read voltage; and
controlling the memory device to perform a second read operation on the cell group with a second read voltage when the first read operation fails and indicates a number of on-cells, which is out of a threshold range, as a result thereof.

20. The operating method of claim 19, further comprising adjusting the first read voltage by a predetermined amount to define the second read voltage.

21. The operating method of claim 20, wherein the adjusting includes:
increasing the first read voltage when the number is less than the threshold range; and
decreasing the first read voltage when the number is greater than the threshold range.

22. The operating method of claim 19, further comprising adjusting the first read voltage by an amount, which corresponds to a deviation of the number with respect to the threshold range, to define the second read voltage.

23. The operating method of claim 22, the adjusting includes:
increasing, when the number is less than the threshold range, the first read voltage by the amount corresponding to the deviation from a lower limit of the threshold range; and
decreasing, when the number is greater than the threshold range, the first read voltage by the amount corresponding to the deviation from an upper limit of the threshold range.
